(19) United States
(12) Patent Application Publication
(10) Pub. No.: US 2026/0221873 A1
(43) Pub. Date: Jul. 30, 2026

(54) CHARGE PUMP CIRCUITS, PERIPHERAL CIRCUITS, MEMORY, MEMORY SYSTEMS AND ELECTRONIC APPARATUS

(71) Applicant: Yangtze Memory Technologies Co., Ltd., Wuhan (CN)

(72) Inventors: Chenyang Li, Wuhan (CN); Lin Miao, Wuhan (CN)

(21) Appl. No.: 19/236,307

(22) Filed: Jun. 12, 2025

(30) Foreign Application Priority Data
Jan. 27, 2025 (CN) 202510127867.1

(51) Int. Cl. H02M 3/07; G11C 5/14; H02M 1/12; H02M 7/217

(52) U.S. Cl. CPC H02M 3/07; G11C 5/145; H02M 1/12; H02M 7/217

(57) ABSTRACT

An example charge pump circuit includes a conversion circuit and a charge pump, wherein an output end of the conversion circuit is coupled with an input end of the charge pump. An example conversion circuit is configured to convert an alternating current signal received at an input end of the conversion circuit into a direct current signal. The charge pump is configured to process the direct current signal to generate an output signal. According to the disclosure, by designing the conversion circuit to convert an alternating current signal that needs to be processed by the charge pump into a direct current signal, (in a case where the alternating current signal is the high-frequency signal) the charge pump may process the direct current signal converted from the high-frequency signal, instead of directly process the high-frequency signal, so that the output signal of the charge pump may meet an expected standard.

### CROSS-REFERENCE TO RELATED APPLICATION

This application claims priority to and the benefit of Chinese Patent Application 202510127867.1, filed on Jan. 27, 2025, which is hereby incorporated by reference in its entirety.

### TECHNICAL FIELD

Examples of the disclosure relate to the field of storage technologies, and in particular, to charge pump circuits, peripheral circuits, memories, memory systems, and electronic apparatus.

### BACKGROUND

A charge pump is a circuit that utilizes the energy storage characteristics of a capacitor to generate an output voltage, and has a wide application in memories.

### BRIEF DESCRIPTION OF THE DRAWINGS

FIG. 1 is a schematic diagram of an input signal and an output signal of a charge pump according to an example of the disclosure;

FIG. 2 is a schematic diagram of a charge pump circuit according to an example of the disclosure;

FIG. 3 is a schematic diagram of a first conversion circuit and a second conversion circuit according to an example of the disclosure;

FIG. 4 is a schematic diagram of a charge pump circuit according to another example of the disclosure;

FIG. 5 is a schematic diagram of a flipping circuit according to an example of the disclosure;

FIG. 6 is a schematic diagram of a charge pump according to an example of the disclosure;

FIG. 7 is a schematic diagram of a peripheral circuit according to an example of the disclosure;

FIG. 8 is a schematic diagram of an example memory device including a memory cell array and a peripheral circuit according to an example of the disclosure;

FIG. 9 is a schematic diagram of a memory according to an example of the disclosure;

FIG. 10 is a schematic diagram of a peripheral circuit according to another example of the disclosure;

FIG. 11 is a structural block diagram of an electronic apparatus according to an example of the disclosure;

FIG. 12 is a structural block diagram of an electronic apparatus according to another example of the disclosure.

### DETAILED DESCRIPTION

In order to clarify the objective, technical solution, and advantage of the disclosure, the examples of the disclosure will be further described in detail with reference to the accompanying drawings hereinafter.

A charge pump is a circuit that utilizes the energy storage characteristics of a capacitor to generate an output voltage. However, due to the process limitations of devices in the charge pump, when the charge pump is configured to process a high-frequency signal, the output signal of the charge pump tends to be difficult to meet an expected standard.

In some examples, a charge pump is configured to identify or detect the difference between two input signals.

In some examples, the charge pump functions to boost a voltage for amplifying the voltage difference between the two input signals. For example, after two direct current signals are input to the charge pump, the charge pump generates output signals with a larger voltage difference.

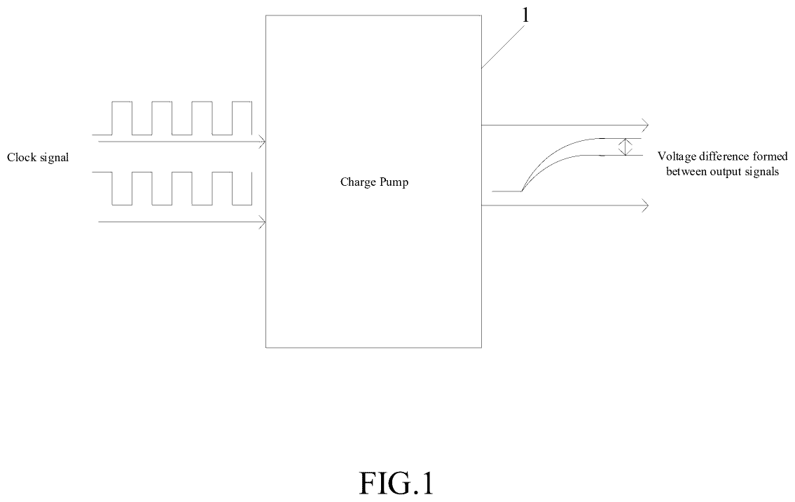

In some examples, the charge pump is configured to identify a pulse width difference between two clock signals in the memory. For example, the magnitude relationship between voltages of two signals output at output ends of the charge pump may reflect the magnitude relationship between pulse widths of two clock signals. As shown in FIG. 1, after two clock signals are input to the charge pump 1, the charge pump 1 outputs two voltage signals, and the voltage difference between the two voltage signals may reflect the foregoing pulse width difference. However, a clock signal in a memory requiring high-speed read/write, such as a dynamic random access memory (DRAM), may have a relatively high frequency, and it may be a relatively high requirement for internal devices of the charge pump 1 to process a high-frequency clock signal. In a case where the pulse width difference between the high-frequency clock signals received by charge pump 1 is small, charge pump 1 may only generate a weak or even erroneous voltage difference, which affects the performance of the memory.

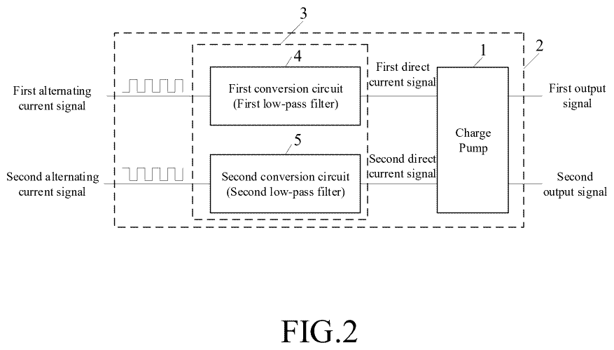

Please refer to FIG. 2, which illustrates a schematic diagram of a charge pump circuit according to an example of the disclosure. The charge pump circuit 2 includes a conversion circuit 3 and a charge pump 1, and an output end of the conversion circuit 3 is coupled to an input end of the charge pump 1.

The conversion circuit 3 is configured to convert the alternating current signal received at an input end of the conversion circuit 3 into a direct current signal.

The charge pump 1 is configured to process the direct current signal to generate an output signal.

In some examples, referring to FIG. 2, the conversion circuit 3 includes a first conversion circuit 4 and a second conversion circuit 5.

The first conversion circuit 4 is configured to convert a first alternating current signal received at an input end of the first conversion circuit 4 into a first direct current signal.

The second conversion circuit 5 is configured to convert a second alternating current signal received at an input end of the second conversion circuit 5 into a second direct current signal.

The charge pump 1 is further configured to process the first direct current signal and the second direct current signal to generate a first output signal and a second output signal.

In some examples, the first alternating current signal includes a first clock signal, the second alternating current signal includes a second clock signal, an amplitude of the first direct current signal is positively correlated with a duty cycle of the first clock signal, and an amplitude of the second direct current signal is positively correlated with a duty cycle of the second clock signal.

In some examples, the amplitude of the first direct current signal is a product of the amplitude of the first voltage and the duty cycle of the first clock signal, and the amplitude of the second direct current signal is a product of the amplitude of the first voltage and the duty cycle of the second clock signal.

In some examples, the first voltage is Vdd in the memory. That is, Vin1=duty1×Vdd, Vin2=duty2×Vdd, wherein Vin1 is the amplitude of the first direct current signal, Vin2 is the amplitude of the second direct current signal, duty1 is the duty cycle of the first clock signal, and duty2 is the duty cycle of the second clock signal. Vdd is an operating voltage supplied to the devices in the memory, and in some examples, it may be considered as a positive supply voltage in the memory (that is, Vdd is a positive voltage relative to a ground terminal voltage in the memory). For example, Vdd is the operating voltage of the charge pump 1, and provides a positive voltage for the sources of P-Metal-Oxide-Semiconductor (PMOS) transistors in the charge pump 1.

In some examples, a voltage difference between the first output signal and the second output signal is configured to reflect a difference between the duty cycle of the first clock signal and the duty cycle of the second clock signal (also to reflect a pulse width difference).

In the foregoing examples, because the amplitude of the first direct current signal is positively correlated with the duty cycle of the first clock signal, and the amplitude of the second direct current signal is positively correlated with the duty cycle of the second clock signal, the task actually performed by the charge pump 1 changes from identifying the duty cycle difference between a pair of clock signals to amplifying the voltage difference between the pair of direct current signals. Due to no longer being affected by the high-frequency characteristics of the device, in a case where there is a difference between the duty cycle of the first clock signal and the duty cycle of the second clock signal, charge pump 1 may output the first output signal and the second output signal with a relatively large voltage difference.

Specifically, in an experiment according to the disclosure, under some set conditions (for example, a memory transmission rate is 3200 picoseconds (ps), a process angle of FS (Fast NMOS Slow PMOS, high-speed NMOS low-speed PMOS) is used, and a temperature is-30 degrees), two clock signals (with a pulse width difference of 2 ps) are input to the charge pump circuit 2, and a voltage difference output by the charge pump circuit 2 is close to 50 millivolts (mv). Under the same setting conditions, when the same two clock signals are directly input into charge pump 1, the voltage difference output by charge pump 1 is merely about 10 mv. It can be seen that charge pump circuit 2 has better performance in recognizing the pulse width difference between the input clock signals.

In addition, in the above example, since the charge pump 1 no longer need to process the alternating current signal and no longer need to realize the swing and pull-up of the signal, the operating current (peak current) thereof is also relatively low, thereby the circuit power consumption is reduced.

TABLE 1

| | the charge pump directly | |
|---|---|---|
| | processes an alternating | the charge pump processes |
| | current signal | a direct current signal |
| Operating Current | 990 microamps (uA) | 490 uA |

As shown in Table 1 above, when the same alternating current signal is processed under the same condition, the operating current of the alternating current signal directly processed by the charge pump 1 is greater than the operating current of the direct current signal processed by the charge pump 1 which is converted from the alternating current signal.

In some examples, the first conversion circuit 4 includes a first low-pass filter, and the second conversion circuit 5 includes a second low-pass filter.

The first alternating current signal is input at an input end of the first low-pass filter, and the second alternating current signal is input at an input end of the second low-pass filter.

An output end of the first low-pass filter and an output end of the second low-pass filter are respectively coupled to different input ends of the charge pump.

In some examples, the first low-pass filter is configured to filter the first alternating current signal to obtain a first direct current signal. The second low-pass filter is configured to filter the second alternating current signal to obtain a second direct current signal.

In the above example, an alternating current signal is converted into a direct current signal through the filter function of the low-pass filter. The space occupied by the low-pass filter is small, thereby a low cost is achieved.

In some examples, the first low-pass filter includes M resistors and M capacitors, the second low-pass filter includes N resistors and N capacitors, both M and N are integers greater than 1, and the M capacitors and the N capacitors are respectively coupled to a ground terminal.

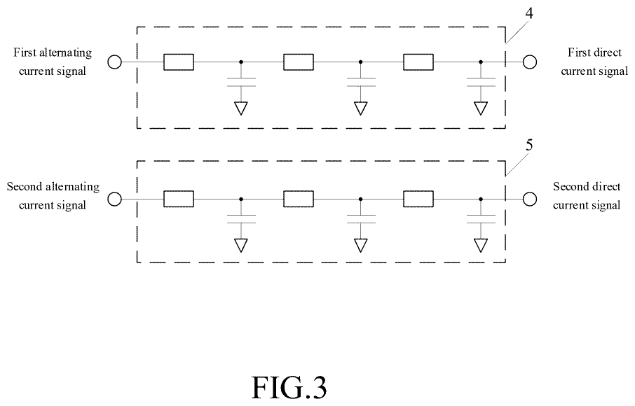

In some examples, M=N. For example, referring to FIG. 3, the first conversion circuit 4 (the first low-pass filter) includes 3 resistors and 3 capacitors, and the second conversion circuit 5 (the second low-pass filter) also includes 3 resistors and 3 capacitors.

In the above example, the first low-pass filter and the second low-pass filter both adopt a low-pass filter of more than one order, so as to ensure that the high-frequency component of the input alternating current signal is completely filtered out, and ensure that the input alternating current signal can be converted into a direct-current signal with stable level.

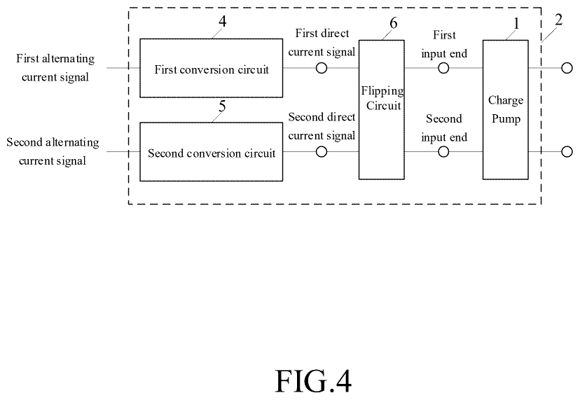

In some examples, referring to FIG. 4, the charge pump circuit 2 further includes a flipping circuit 6. Input ends of the flipping circuit 6 are respectively coupled to the output end of the first conversion circuit 4 and the output end of the second conversion circuit 5, and output ends of the flipping circuit 6 are respectively coupled to the first input end and the second input end of the charge pump 1.

The flipping circuit 6 is configured to: in a case that first information is received, transmit the first direct current signal to the first input end of the charge pump 1 and transmit the second direct current signal to the second input end of the charge pump 1; and in a case that second information is received, transmit the first direct current signal to the second input end of the charge pump 1 and transmit the second direct current signal to the first input end of the charge pump 1.

The first information is different from the second information.

In some examples, the flipping circuit is configured to: in a case that first information is received, couple the output end of the first conversion circuit 4 (first low-pass filter) to the first input end of the charge pump 1 and couple the output end of the second conversion circuit 5 to the second input end of the charge pump 1; and in a case that second information is received, couple the output end of the first conversion circuit 4 (first low-pass filter) to the second input end of the charge pump 1 and couple the output end of the second conversion circuit 5 to the first input end of the charge pump 1.

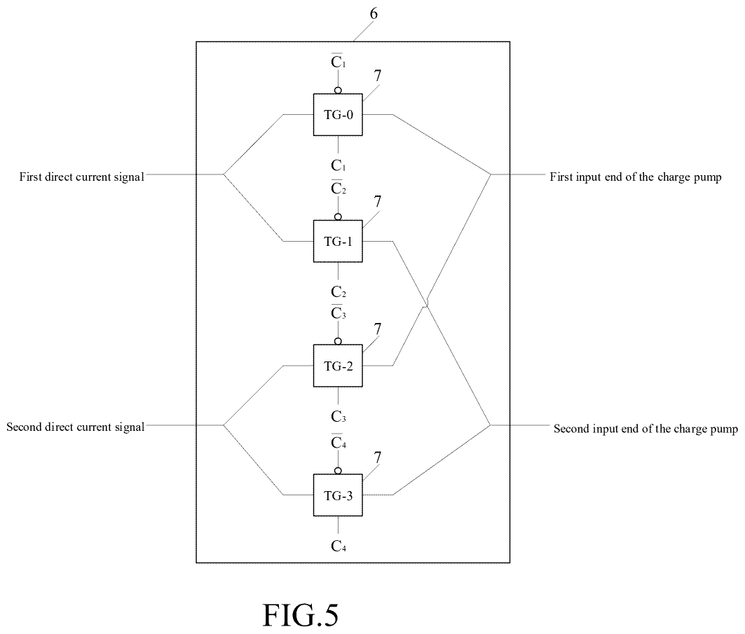

In some examples, referring to FIG. 5, the flipping circuit 6 includes 4 transmission gates (TG) 7, and the first information and the second information are control signals for the 4 transmission gates. When the first information is received, TG-0 and TG-3 are gated (TG-1 and TG-2 are turned off), so that the first direct current signal is transmitted to the first input end of the charge pump 1, and the second direct current signal is transmitted to the second input end of the charge pump 1. When the second information is received, TG-1 and TG-2 are gated (TG-0 and TG-3 are turned off), so that the first direct current signal is transmitted to the second input end of the charge pump 1, and the second direct current signal is transmitted to the first input end of the charge pump 1.

In the foregoing examples, the flipping circuit 6 supports flipping the port for inputting the first direct current signal and the second direct current signal to the ends of the charge pump 1 according to different information (the first information and the second information), thereby improving flexibility of input adjustment. Moreover, since the alternating current signal is converted into a direct current signal, the flipping circuit 6 only needs to support the gating of the direct current signal, and various transmission gate circuits may be used to achieve the foregoing flipping function, resulting in lower implementation costs.

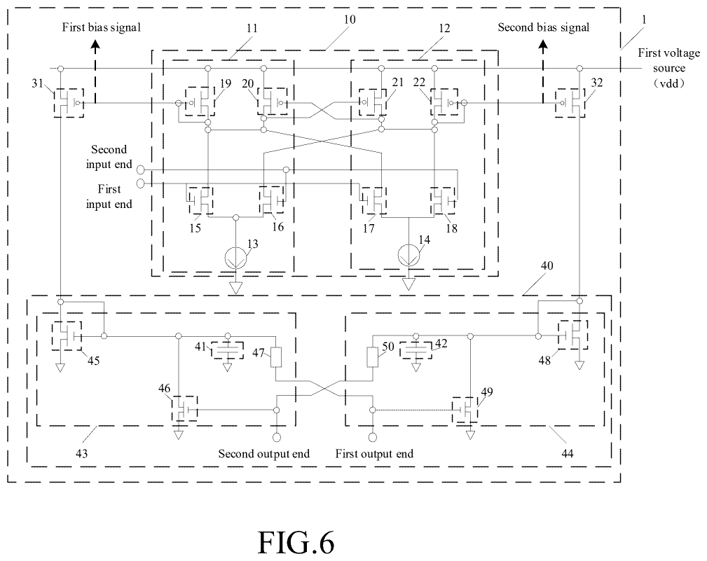

In some examples, referring to FIG. 6, the charge pump 1 includes an input circuit 10, a first PMOS transistor 31, a second PMOS transistor 32, and an output circuit 40, wherein the gate of the first PMOS transistor 31 is coupled to the input circuit 10, the drain of the first PMOS transistor 31 is coupled to the output circuit 40, the source of the first PMOS transistor 31 is coupled to a first voltage source, the gate of the second PMOS transistor 32 is coupled to the input circuit 10, the drain of the second PMOS transistor 32 is coupled to the output circuit 40, the source of the second PMOS transistor 32 is coupled to the first voltage source, and the output circuit 40 includes a first capacitor 41 and a second capacitor 42.

The input circuit 10 is configured to generate a first bias signal to be provided to (the gate of) the first PMOS transistor 31 and a second bias signal to be provided to (the gate of) the second PMOS transistor 32 according to the first direct current signal and the second direct current signal.

The output circuit 40 is configured to charge the first capacitor 41 through a first current to generate the first output signal, and charge the second capacitor 42 through a second current to generate the second output signal.

The first current includes a drain current of the first PMOS transistor 31 under control of the first bias signal, and the second current includes a drain current of the second PMOS transistor 32 under control of the second bias signal.

In the charge pump 1, due to the process limitations of the MOS transistor, the first PMOS transistor 31 and the second PMOS transistor 32 in the input circuit, when processing a signal with a relatively high frequency, even if there is a pulse width difference between the input clock signals, the first PMOS transistor 31 and the second PMOS transistor 32 may not be able to generate a relatively large drain current difference, resulting in that once the following output circuit is mismatched (e.g., the symmetrical components may not be completely the same due to process reasons, such as inconsistent sizes), the finally generated voltage difference may be small, and even a voltage difference opposite to the real situation may occur. However, in this solution, the charge pump 1 processes the direct current signal, and the charge pump is actually used to amplify the voltage difference between the direct current signals without being limited by a high-frequency characteristic of the device, so that when there is a pulse width difference between the clock signals before conversion, the first PMOS transistor 31 and the second PMOS transistor 32 may generate a relatively large drain current difference, therefore the charge pump 1 outputs a relatively large voltage difference. Please refer to table 2 below, which shows the drain current of the first PMOS transistor 31, the drain current of the second PMOS transistor 32 and the difference thereof measured in specific experiments of the present disclosure.

TABLE 2

| Unit: uA | Case 1 | Case 2 | Case 3 |
|---|---|---|---|
| I₃₁ | 124 | 81 | 90 |
| I₃₂ | 123 | 79 | 55 |
| ΔI | 1 | 2 | 35 |

In Table 2, I₃₁ is the drain current of the first PMOS transistor 31 (taking the average current value when it is stable), I₃₂ is the drain current of the second PMOS transistor 32 (taking the average current value when it is stable), ΔI is the difference between the two. Case 1 is the case in which the charge pump 1 is directly configured to process the alternating current signal, Case 2 is the case in which the charge pump 1 is directly configured to process the alternating current signal after the internal device in the charge pump 1 is improved (for example, the size of the device is matched), Case 3 is the case in which the charge pump 1 is configured to process the direct current signal converted from the alternating current signal, and other operating conditions of the above 3 cases are the same. It can be learned that for the same alternating current signals (with a same pulse width difference), ΔI in case 3 is much greater than ΔI in case 1 and ΔI in case 2. By using the technical solution according to examples of the disclosure, the alternating current signals are converted into direct current signals, and the direct current signals are input to the charge pump 1. With a pulse width difference between the alternating current signals, the first PMOS transistor 31 and the second PMOS transistor 32 may generate larger drain current difference, so that the charge pump 1 output larger voltage difference.

In some examples, the charge pump 1 further includes a first switch structure and a second switch structure (not shown in FIG. 6).

One end of the first switch structure is coupled to the drain of the first PMOS transistor 31, and the other end of the first switch structure is coupled to the output circuit 40. One end of the second switch structure is coupled to the drain of the second PMOS transistor 32, and the other end of the second switch structure is coupled to the output circuit 40.

In the above example, the static leakage phenomenon in the charge pump 1 may be reduced by adding a switch structure on the drain paths of the first PMOS transistor 31 and the second PMOS transistor 32.

TABLE 3

| | With Switch | Without Switch |
|---|---|---|
| | structure | structure |
| Leakage Current | 15 uA | 700 nA |

As shown in Table 3 above, when the charge pump 1 is not in operation, adding a switch structure to turn off the drain paths of the first PMOS transistor 31 and the second PMOS transistor 32 helps to reduce the leakage current of the charge pump 1, thereby saving power consumption.

In some examples, referring to FIG. 6, the input circuit 10 includes a first input structure 11 and a second input structure 12, the number of metal oxide semiconductor (MOS) transistors included in the first input structure 11 is the same as the number of MOS transistors included in the second input structure 12, the gate of the first PMOS transistor 31 is coupled to the first input structure 11, and the gate of the second PMOS transistor 32 is coupled to the second input structure 12.

In some examples, referring to FIG. 6, the first input structure 11 includes a first current source 13, a first N-Metal-Oxide-Semiconductor (NMOS) transistor 15, and a second NMOS transistor 16, and the second input structure 12 includes a second current source 14, a third NMOS transistor 17, and a fourth NMOS transistor 18.

The first current source 13 is coupled to the source of the first NMOS transistor 15 and the source of the second NMOS transistor 16, respectively, and the second current source 14 is coupled to the source of the third NMOS transistor 17 and the source of the fourth NMOS transistor 18, respectively.

The gate of the first NMOS transistor 15 and the gate of the third NMOS transistor 17 are coupled to the first input end of the charge pump 1, respectively.

The gate of the second NMOS transistor 16 and the gate of the fourth NMOS transistor 18 are coupled to the second input end of the charge pump 1, respectively.

In the foregoing examples, the first input structure 11 and the second input structure 12 enable that the first direct current signal and the second direct current signal are input into the charge pump 1 in a form of differential input, so that the voltage difference between the first bias signal and the second bias signal provided by the input circuit 10 may reflect the voltage difference between the first direct current signal and the second direct current signal.

In some examples, referring to FIG. 6, the first input structure 11 further includes a third PMOS transistor 19 and a fourth PMOS transistor 20, and the second input structure 12 further includes a fifth PMOS transistor 21 and a sixth PMOS transistor 22.

The source of the third PMOS transistor 19, the source of the fourth PMOS transistor 20, the source of the fifth PMOS transistor 21, and the source of the sixth PMOS transistor 22 are coupled to the first voltage source, respectively.

The drain of the first NMOS transistor 15, the drain of the third NMOS transistor 17, the drain of the third PMOS transistor 19, the gate of the third PMOS transistor 19, the drain of the fourth PMOS transistor 20, and the gate of the fifth PMOS transistor 21 are coupled to the gate of the first PMOS transistor 31, respectively.

The drain of the second NMOS transistor 16, the drain of the fourth NMOS transistor 18, the drain of the sixth PMOS transistor 22, the gate of the sixth PMOS transistor 22, the drain of the fifth PMOS transistor 21, and the gate of the fourth PMOS transistor 20 are coupled to the gate of the second PMOS transistor 32, respectively.

In the foregoing examples, the PMOS transistors in the first input structure 11 and the second input structure 12 are cross-coupled, to implement positive feedback for differential input, and ensure that a relatively large voltage difference is obtained between the first bias signal and the second bias signal when a voltage difference exists between the first direct current signal and the second direct current signal.

In some examples, referring to FIG. 6, the output circuit 40 includes a first output structure 43 and a second output structure 44, the number of MOS transistors included in the first output structure 43 is the same as the number of MOS transistors included in the second output structure 44, the drain of the first PMOS transistor 31 is coupled to the first output structure 43, and the drain of the second PMOS transistor 32 is coupled to the second output structure 44.

In some examples, referring to FIG. 6, the first output structure 43 includes a fifth NMOS transistor 45, a sixth NMOS transistor 46, a first capacitor 41 and a first resistor 47, and the second output structure 44 includes a seventh NMOS transistor 48, an eighth NMOS transistor 49, a second capacitor 42 and a second resistor 50.

The drain of the first PMOS transistor 31 is coupled to the drain of the fifth NMOS transistor 45, the gate of the fifth NMOS transistor 45, the drain of the sixth NMOS transistor 46, one end of the first capacitor 41, and one end of the first resistor 47, respectively.

The source of the fifth NMOS transistor 45, the source of the sixth NMOS transistor 46, and the other end of the first capacitor 41 are coupled to a ground terminal, respectively.

The drain of the second PMOS transistor 32 is coupled to the drain of the seventh NMOS transistor 48, the gate of the seventh NMOS transistor 48, the drain of the eighth NMOS transistor 49, one end of the second capacitor 42, and one end of the second resistor 50, respectively.

The source of the seventh NMOS transistor 48, the source of the eighth NMOS transistor 49, and the other end of the second capacitor 42 are coupled to the ground terminal, respectively.

The other end of the first resistor 47 and the gate of the eighth NMOS transistor 49 are coupled to the first output end of the charge pump 1 respectively, and the other end of the second resistor 50 and the gate of the sixth NMOS transistor 46 are coupled to the second output end of the charge pump 1, respectively.

In the above example, the first bias signal provides a bias voltage to the gate of the first PMOS transistor 31, and the second bias signal provides a bias voltage to the gate of the second PMOS transistor 32. In the case that the voltages of the first bias signal and the second bias signal are inconsistent, since the sources of the first PMOS transistor 31 and the second PMOS transistor 32 are both coupled to the same voltage source (e.g., the first voltage source), (the average value of) the drain current of the first PMOS transistor 31 is also different from (the average value of) the drain current of the second PMOS transistor 32, and since the drain current of the first PMOS transistor 31 may charge the first capacitor 41, and the drain current of the second PMOS transistor 32 may charge the second capacitor 42, a voltage difference is formed between a voltage generated by the energy storage of the first capacitor 41 and a voltage generated by the energy storage of the second capacitor 42, and a voltage difference is formed between the two output ends. And since the voltage generated by the first capacitor 41 provides the bias voltage of the gate for the fifth NMOS transistor 45, the voltage generated by the second capacitor 42 provides the bias voltage of the gate for the seventh NMOS transistor 48, the output signal of the first output end provides the bias voltage of the gate for the eighth NMOS transistor 49, and the output signal of the second output end provides the bias voltage of the gate for the sixth NMOS transistor 46. Therefore, in a case where the voltage generated by the first capacitor 41 is different from the voltage generated by the second capacitor 42 (that is, the bias voltages provided to the fifth NMOS transistor 45 and the seventh NMOS transistor 48 are different), and there is a voltage difference between the output signals of the two output ends (that is, the bias voltages provided to the sixth NMOS transistor 46 and the eighth NMOS transistor 49 are different), the fifth NMOS transistor 45, the sixth NMOS transistor 46, the seventh NMOS transistor 48, and the eighth NMOS transistor 49 may be able to achieve positive feedback for the voltage difference between the output signals, so that the voltage difference between the two output signals is more obvious, thereby amplifying the voltage difference between the first direct current signal and the second direct current signal.

It can be seen that from the first input structure 11, the second input structure 12, the first PMOS transistor 31, the second PMOS transistor 32, the first output structure 43, and the second output structure 44 described above, the charge pump 1 adopts a symmetric structure. When the charge pump 1 is configured to process two clock signals with a pulse width difference, as a mismatch phenomenon of the charge pump 1 affects significantly to a high-frequency signal processing procedure, it is difficult for the charge pump 1 to form a stable voltage difference that can be identified in a case where the pulse width difference between two clock signals is relatively small. Specifically, in an experiment according to the disclosure, multiple tests are performed on the charge pump 1 under a same condition (a same memory transmission rate, and a same pulse width difference between two input clock signals), and the charge pump 1 is configured to directly process two high-frequency clock signals in each test. As a result, an identifiable stable voltage difference may not be formed between the two signals output by the charge pump 1 in most tests. It can be seen that when the charge pump 1 is configured to process a high-frequency clock signal, the mismatch phenomenon has a significant impact on its performance. In addition, in another experiment according to the disclosure, multiple tests are performed on the charge pump circuit 2 under a same condition (a same memory transmission rate, and a same pulse width difference between two input clock signals), and in each test, the charge pump 1 processes two direct current signals converted from two high-frequency clock signals input to the charge pump circuit 2 As a result, an identifiable stable voltage difference may be formed between the two signals output by the charge pump 1 in all tests. It can be seen that when the charge pump 1 is configured to process a direct current signal, the mismatch phenomenon has less impact on its performance, that is, the charge pump 1 may be able to tolerate a larger mismatch. Therefore, when the foregoing charge pump circuit 2 is configured to identify the pulse width difference between the two clock signals input, it has extremely high reliability and stability.

In addition, in examples of the disclosure, the signal input to the charge pump 1 is a direct current signal, the charge pump 1 no longer need to process a high-frequency signal, and a requirement of processing the direct current signal on a device specifications is relatively low, therefore the above scheme further reduce the cost of disposing the devices in the charge pump 1. For example, the devices in the charge pump 1 may be adjusted by the person skilled in the art as required, for example, the size of a capacitor and a resistor in the charge pump 1 may be reduced to reduce the footprint occupied by the charge pump 1.

The following describes examples of a peripheral circuit, a memory, a memory system, an electronic apparatus, and the like according to the disclosure. For content that is not described in detail in the following examples, please refer to the foregoing memory examples.

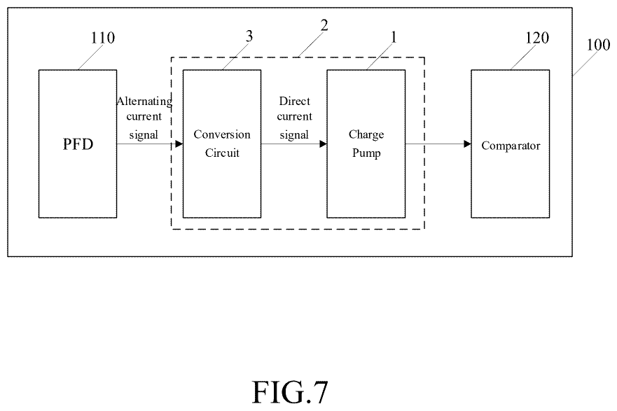

Please refer to FIG. 7, which illustrates a schematic diagram of a peripheral circuit according to an example of the disclosure. The peripheral circuit 100 includes a Phase Frequency Detector (PFD) 110, a charge pump circuit 2, and a comparator 120, wherein the charge pump circuit 2 includes a conversion circuit 3 and a charge pump 1, an input end of the conversion circuit 3 is coupled to the PFD 110, an output end of the conversion circuit 3 is coupled to an input end of the charge pump 1, and an output end of the charge pump 1 is coupled to the comparator 120.

The signal received at an input end of the conversion circuit 3 includes an alternating current signal, and the signal output at an output end of the conversion circuit 3 includes a direct current signal. In some examples, PFD 110 is configured to provide the foregoing alternating current signal, and the comparator 120 is configured to compare the output signals of charge pump 1.

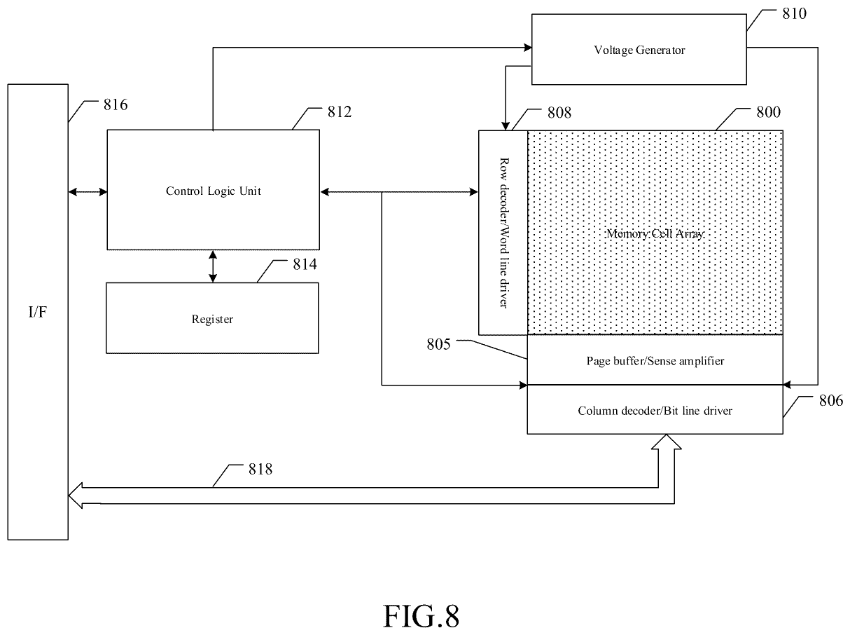

It should be noted that, in addition to the PFD 110, the charge pump circuit 2, and the comparator 120 described above, the peripheral circuit 100 may further include other devices. For example, FIG. 8 illustrates some example peripheral circuits, and the peripheral circuit 100 further includes a page buffer/sense amplifier 805, a column decoder/bit line driver 806, a row decoder/word line driver 808, a voltage generator 810, a control logic unit 812, a register 814, an interface 816, and a data bus 818. It should be understood that, in some examples, the peripheral circuit 100 may further include additional peripheral circuits not mentioned above.

The page buffer/sense amplifier 805 may be configured to read data from the memory cell array 800 and program (write data to) the memory cell array 800 according to control signals from the control logic 812. In one example, the page buffer/sense amplifier 805 may store a page of program data (write data) to be programmed to the memory cell array 800. In another example, the page buffer/sense amplifier 805 may perform a program verify operation to ensure that data has been correctly programmed into memory cells coupled to the selected word line. In yet another example, the page buffer/sense amplifier 805 may also sense a low power signal from a bit line representing a data bit stored in a memory cell and amplify a small voltage swing to an identifiable logic level in a read operation. Column decoder/bit line driver 806 may be configured to be controlled by the control logic unit 812 and to select one or more memory strings by applying a bit line voltage generated from voltage generator 810.

The row decoder/word line driver 808 may be configured to be controlled by the control logic unit 812 and select/deselect a block in the memory cell array and select/deselect a word line of the block (to which the memory cells within the block are coupled). The row decoder/word line driver 808 may also be configured to drive word line using word line voltages generated from the voltage generator 810. In some examples, the row decoder/word line driver 808 may also select/deselect and drive Drain Select Gate (DSG) lines and Source Select Gate (SSG) lines. In some examples, the row decoder/word line driver 808 is further configured to perform an erase operation on the memory cell(s) coupled to the selected word line. The voltage generator 810 may be configured to be controlled by the control logic unit 812 and generate word line voltages (e.g., read voltages, program voltages, pass voltages, local voltages, verify voltages, etc.), bit line voltages, and source line voltages to be supplied to the memory cell array 800.

The control logic unit 812 may be coupled to each peripheral circuit described above and configured to control operation of each peripheral circuit. Registers 814 may be coupled to control logic unit 812 and include status registers, command registers, and address registers for storing status information, command operation codes (OP codes), and command addresses for controlling operation of each peripheral circuit. Interface 816 may be coupled to control logic unit 812 and act as a control buffer to buffer and relay control commands received from a host (not shown in FIG. 8) to control logic unit 812 and to buffer and relay status information received from control logic unit 812 to the host. The interface 816 may also be coupled to the column decoder/bit line driver 806 via the data bus 818 and act as a data Input/Output (I/O) interface and data buffer, to buffer and relay data to the memory cell array 800, or relay or buffer data from the memory cell array 800.

In some examples, the conversion circuit 3 includes a first conversion circuit and a second conversion circuit, the first conversion circuit is configured to convert the first alternating current signal received at the input end of the first conversion circuit into a first direct current signal, the second conversion circuit is configured to convert the second alternating current signal received at the input end of the second conversion circuit into a second direct current signal, and the charge pump is configured to process the first direct current signal and the second direct current signal to generate a first output signal and a second output signal.

In some examples, the first conversion circuit includes a first low-pass filter, and the second conversion circuit includes a second low-pass filter. The first alternating current signal is input at an input end of the first low-pass filter, and the second alternating current signal is input at an input end of the second low-pass filter. An output end of the first low-pass filter and an output end of the second low-pass filter are coupled to different input ends of the charge pump, respectively.

In some examples, the first low-pass filter includes M resistors and M capacitors, the second low-pass filter includes N resistors and N capacitors, both M and N are integers greater than 1, and the M capacitors and the N capacitors are coupled to the ground terminal, respectively.

In some examples, the charge pump circuit 2 further includes a flipping circuit. Input ends of the flipping circuit are coupled to the output end of the first conversion circuit and the output end of the second conversion circuit respectively, and the output ends of the flipping circuit are coupled to the first input end and the second input end of the charge pump, respectively. The flipping circuit is configured to transmit the first direct current signal to the first input end of the charge pump and transmit the second direct current signal to the second input end of the charge pump in a case that a first information is received, and transmit the first direct current signal to the second input end of the charge pump and transmit the second direct current signal to the first input end of the charge pump in a case that a second information is received, wherein the first information is different from the second information.

In some examples, the charge pump 1 includes an input circuit, a first P-type metal-oxide-semiconductor (PMOS) transistor, a second PMOS transistor, and an output circuit. The gate of the first PMOS transistor is coupled to the input circuit, the drain of the first PMOS transistor is coupled to the output circuit, the source of the first PMOS transistor is coupled to a first voltage source, the gate of the second PMOS transistor is coupled to the input circuit, the drain of the second PMOS transistor is coupled to the output circuit, and the source of the second PMOS transistor is coupled to the first voltage source. The output circuit includes a first capacitor and a second capacitor. The input circuit is configured to generate a first bias signal to be provided to the first PMOS transistor and a second bias signal to be provided to the second PMOS transistor according to the first direct current signal and the second direct current signal. The output circuit is configured to charge the first capacitor through a first current to generate a first output signal, and charge the second capacitor through a second current to generate a second output signal, wherein the first current includes a drain current of the first PMOS transistor under control of the first bias signal, and the second current includes a drain current of the second PMOS transistor under control of the second bias signal.

In some examples, the charge pump 1 further includes a first switch structure and a second switch structure, wherein one end of the first switch structure is coupled to the drain of the first PMOS transistor, the other end of the first switch structure is coupled to the output circuit, one end of the second switch structure is coupled to the drain of the second PMOS transistor, and the other end of the second switch structure is coupled to the output circuit.

In some examples, the input circuit includes a first input structure and a second input structure, wherein the number of MOS transistors included in the first input structure is the same as the number of MOS transistors included in the second input structure, the gate of the first PMOS transistor is coupled to the first input structure, and the gate of the second PMOS transistor is coupled to the second input structure.

In some examples, the first input structure includes a first current source, a first N-type metal oxide semiconductor (NMOS) transistor, and a second NMOS transistor. The second input structure includes a second current source, a third NMOS transistor, and a fourth NMOS transistor. The first current source is coupled to the source of the first NMOS transistor and the source of the second NMOS transistor respectively, and the second current source is coupled to the source of the third NMOS transistor and the source of the fourth NMOS transistor, respectively. The gate of the first NMOS transistor and the gate of the third NMOS transistor are coupled to the first input end of the charge pump, respectively, and the gate of the second NMOS transistor and the gate of the fourth NMOS transistor are coupled to the second input end of the charge pump, respectively.

In some examples, the first input structure further includes a third PMOS transistor and a fourth PMOS transistor, the second input structure further includes a fifth PMOS transistor and a sixth PMOS transistor. The source of the third PMOS transistor, the source of the fourth PMOS transistor, the source of the fifth PMOS transistor, and the source of the sixth PMOS transistor are coupled to the first voltage source respectively, the drain of the first NMOS transistor, the drain of the third NMOS transistor, the drain of the third PMOS transistor, the gate of the third PMOS transistor, the drain of the fourth PMOS transistor, and the gate of the fifth PMOS transistor are coupled to the gate of the first PMOS transistor respectively, and the drain of the second NMOS transistor, the drain of the fourth NMOS transistor, the drain of the sixth PMOS transistor, the gate of the sixth PMOS transistor, the drain of the fifth PMOS transistor, and the gate of the fourth PMOS transistor are coupled to the gate of the second PMOS transistor respectively.

In some examples, the output circuit includes a first output structure and a second output structure, the number of MOS transistors included in the first output structure is the same as the number of MOS transistors included in the second output structure, the drain of the first PMOS transistor is coupled to the first output structure, and the drain of the second PMOS transistor is coupled to the second output structure.

In some examples, the first output structure includes a fifth NMOS transistor, a sixth NMOS transistor, a first capacitor and a first resistor. The second output structure includes a seventh NMOS transistor, an eighth NMOS transistor, a second capacitor, and a second resistor. The drain of the first PMOS transistor is coupled to the drain of the fifth NMOS transistor, the gate of the fifth NMOS transistor, the drain of the sixth NMOS transistor, one end of the first capacitor, and one end of the first resistor, respectively. The source of the fifth NMOS transistor, the source of the sixth NMOS transistor, and the other end of the first capacitor are coupled to the ground terminal, respectively. The drain of the second PMOS transistor is coupled to the drain of the seventh NMOS transistor, the gate of the seventh NMOS transistor, the drain of the eighth NMOS transistor, one end of the second capacitor, and one end of the second resistor, respectively. The source of the seventh NMOS transistor, the source of the eighth NMOS transistor, and the other end of the second capacitor are coupled to the ground terminal, respectively. The other end of the first resistor and the gate of the eighth NMOS transistor are coupled to the first output end of the charge pump 1, respectively, and the other end of the second resistor and the gate of the sixth NMOS transistor are coupled to the second output end of the charge pump 1, respectively.

In some examples, the first alternating current signal includes a first clock signal, the second alternating current signal includes a second clock signal, the amplitude of the first direct current signal is positively correlated with the duty cycle of the first clock signal, and the amplitude of the second direct current signal is positively correlated with the duty cycle of the second clock signal.

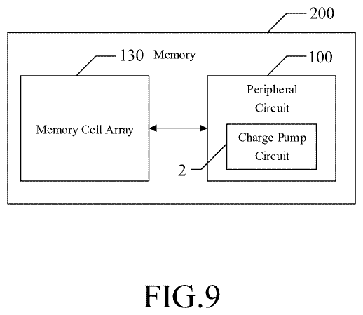

Please refer to FIG. 9, which illustrates a schematic diagram of a memory according to an example of the disclosure. The memory 200 includes a memory cell array 130 and a peripheral circuit 100, and the peripheral circuit 100 includes charge pump circuit 2.

In some examples, the memory 200 includes a plurality of memory banks and a peripheral circuit 100. Each memory bank includes a plurality of memory cells, and the memory cells are arranged in an array form in the memory bank, that is, each memory bank includes at least one memory cell array 130.

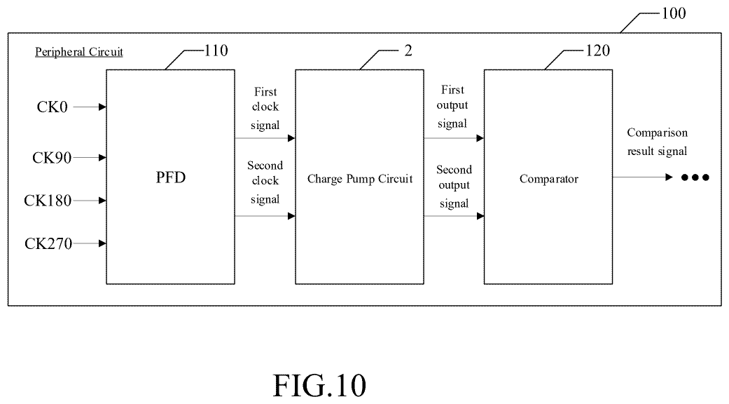

In some examples, referring to FIG. 10, the peripheral circuit 100 further includes PFD 110 and a comparator 120.

In some examples, a Duty Cycle Monitor (DCM) is included in the peripheral circuit 100. The DCM includes the PFD 110, the charge pump circuit 2, and the comparator 120 described above, and the DCM is configured to monitor the duty cycle of the clock signals in memory 200.

In some examples, the DCM is configured to detect the magnitude relationship between the duty cycle of a Write Clock (WCK) signal of the memory 200 and a target duty cycle. In some examples, the target duty cycle includes 50%.

The PFD 110 is configured to: obtain a first clock signal and a second clock signal input to the charge pump according to a plurality of frequency division signals of the WCK signal of the memory, wherein frequencies of the first clock signal and the second clock signal are the same as the frequency of the WCK signal, and duty cycles of the first clock signal and the second clock signal are associated with the duty cycle of the WCK signal.

The WCK signal is configured to control a timing of a write operation in the memory 200, and the multiple frequency division signals of the WCK signal refer to multiple signals with different frequencies obtained based on the WCK signal. For example, referring to FIG. 10, CK0, CK90, CK180, and CK270 are four frequency division signals with different frequencies obtained based on the WCK signal.

In some examples, the duty cycle of the first clock signal is the same as the duty cycle of the WCK signal, and the first clock signal and the second clock signal are complementary. Therefore, by detecting the pulse width difference between the first clock signal and the second clock signal, the magnitude relationship between the duty cycle of the WCK signal and the target duty cycle may be identified.

The comparator 120 is configured to obtain a comparison result signal according to the first output signal and the second output signal of the charge pump 1, where the comparison result signal is configured to indicate the magnitude relationship between the duty cycle of the WCK signal and the target duty cycle.

In some examples, the comparator 120 is configured to compare the voltage of the first output signal with the voltage of the second output signal to obtain the comparison result signal.

For example, in a case where the voltage of the first output signal is greater than the voltage of the second output signal, the comparison result signal output by the comparator 120 indicates that the duty cycle of the WCK signal is greater than the target duty cycle. In a case where the voltage of the first output signal is less than the voltage of the second output signal, the comparison result signal output by the comparator 120 indicates that the duty cycle of the WCK signal is less than the target duty cycle.

In the foregoing example, by designing PFD 110 to restore a plurality of frequency division signals of the WCK to the first clock signal and the second clock signal that may reflect the duty cycle of the WCK signal, detection of the duty cycle of the WCK signal may be performed based on the frequency division signals of the WCK signal instead of performing detection on the WCK signal, so that the DCM may be disposed close to the memory cell array 130 instead of being disposed close to an occurrence position of the WCK signal, thereby improving actual utility of detecting the duty cycle of the WCK signal by the DCM.

In some examples, the peripheral circuit 100 further includes a duty cycle adjustment circuit.

In some examples, the duty cycle adjustment circuit is coupled to an output end of the comparator 120.

The duty cycle adjustment circuit is configured to adjust the duty cycle of the WCK signal according to the comparison result signal output by the comparator. For example, if the comparison result signal indicates that the duty cycle of the WCK signal is greater than the target duty cycle, the duty cycle adjustment circuit reduces the duty cycle of the WCK signal, and if the comparison result signal indicates that the duty cycle of the WCK signal is less than the target duty cycle, the duty cycle adjustment circuit increases the duty cycle of the WCK signal.

The charge pump circuit 2 according to examples of the disclosure may output a relatively large voltage difference when the pulse width difference between input clock signals is relatively small, thereby improving precision of detecting the duty cycle of the WCK signal by the DCM. It is particularly applicable to Dynamic Random Access Memory (DRAM) with high precision requirements for duty cycle control of the WCK signal. However, it should be understood that the function of the charge pump circuit 2 is not limited to the detection of the duty cycle of the WCK signal, and the memory 200 is not limited to the DRAM. For example, the memory 200 may also include any other memory that may use a charge pump, such as Static Random Access Memory (SRAM), Not AND Flash (NAND Flash), Not OR Flash (NOR Flash), etc., which is not limited in the disclosure.

In some examples, a memory system is further provided, including a controller and a memory according to any example of the disclosure, and the controller is coupled to the memory to control the memory to store data.

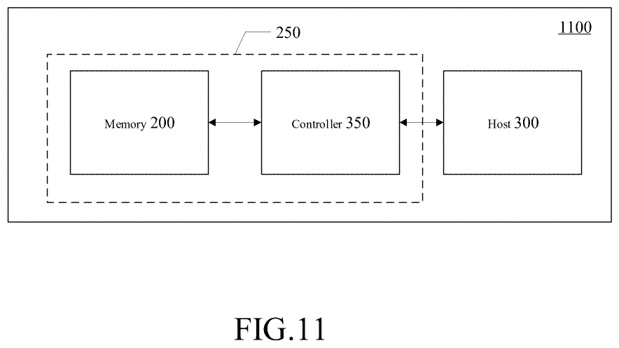

Please refer to FIG. 11, which illustrates a structural block diagram of electronic apparatus according to an example of the disclosure. The electronic apparatus 1100 includes a memory system 250 and a host 300. The memory system 250 includes a controller 350 and a memory 200 according to any example of the disclosure. The electronic apparatus 1100 may be a mobile phone, a desktop computer, a laptop computer, a tablet computer, a vehicle-mounted computer, a game console, a printer, a positioning device, a wearable electronic device, an intelligent sensor, a virtual reality (VR) device, an augmented reality (AR) device, or any other suitable electronic apparatus having a memory system therein. The host 300 may include a processor of the electronic apparatus, such as a central processing unit (CPU), or a system on chip (SoC), such as an application processor (AP). The host 300 may be configured to send data to the memory 200 or receive data from the memory 200. In some examples, controller 350 is coupled to the memory 200 and the host 300 and is configured to control the memory 200. The controller 350 may manage data stored in the memory 200 and communicate with the host 300. The controller 350 may be configured to control operations of the memory 200, such as read, write, and refresh operations. The controller 350 may also be configured to manage various functions regarding data stored or to be stored in the memory 200, including but not limited to refresh and timing control, command/request translation, buffering and scheduling, and power management. In some examples, the controller 350 is further configured to determine maximum memory capacity, number of memory ranks, memory type and speed, memory particle data depth and data width, and other important parameters that the electronic apparatus can use. The controller 350 may also perform any other suitable function. The controller 350 may communicate with an external device (e.g., host 300) according to a particular communication protocol. For example, the controller 350 may communicate with an external device over at least one of various interface protocols, such as a Universal Serial Bus (USB) protocol, a Multi-Media Card (MMC) protocol, a Peripheral Component Interconnect (PCI) protocol, a PCI-Express (PCI-E) protocol, an Advanced Technology Attachment (ATA) protocol, a Serial ATA protocol, a Parallel ATA protocol, a Small Computer System Interface (SCSI) protocol, an Enhanced Small Drive Interface (ESDI) protocol, an Integrated Design Electronics (IDE) protocol, a Firewire protocol, and the like. In addition, it should be noted that there may be one or more memories 200 coupled to the controller 350, which is not limited in the disclosure.

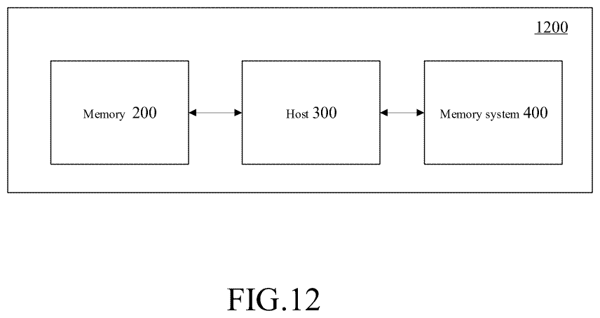

Please refer to FIG. 12, which illustrates a structural block diagram of electronic apparatus according to another example of the disclosure. The electronic apparatus 1200 includes a memory system 400, a host 300, and a memory 200 according to any example of the disclosure. The host 300 may be a processor of an electronic apparatus, such as a CPU, and the host 300 is coupled to the memory 200 and the memory system 400, respectively. In some examples, the memory 200 may be a memory for temporarily storing operation data of the processor (the host 300), and the memory 200 may be a volatile memory (VM), such as a DRAM. The memory system 400 may include a non-volatile memory (NVM), such as a flash memory, different from the memory 200. Memory system 400 may also include a controller, such as a flash memory controller, coupled with the non-volatile memory. In some examples, the memory system 400 may further include a controller of the memory 200, such as a DRAM controller, and the controller may be configured to control temporarily storing of data stored in the memory system 400 into the memory 200. In addition, it should be noted that there may be one or more memories 200 coupled to the host 300, which is not limited in the disclosure.

In summary, the memory according to examples of the disclosure may be coupled to the host through the controller, or may be directly coupled to the host, which is not limited in the disclosure.

The term “multiple” herein refers two or more. The term “and/or” describes an association relationship of associated objects, and indicates that there may be three types of relationships, for example, A and/or B may include three cases: A alone, A and B together, and B alone. The character “/” generally indicates that the associated objects have an “or” relationship.

The examples of the disclosure provide a charge pump circuit, a peripheral circuit, a memory, a memory system and electronic apparatus. The technical solutions according to examples of the disclosure are as follows.

According to an aspect of an example of the disclosure, a charge pump circuit is provided, including a conversion circuit and a charge pump, and an output end of the conversion circuit is coupled to an input end of the charge pump.

The conversion circuit is configured to convert an alternating current signal received at an input end of the conversion circuit into a direct current signal.

The charge pump is configured to process the direct current signal to generate an output signal.

According to an aspect of an example of the disclosure, a peripheral circuit is provided, including a Phase Frequency Detector (PFD), a charge pump circuit, and a comparator. The charge pump circuit includes a conversion circuit and a charge pump. An input end of the conversion circuit is coupled to the PFD, an output end of the conversion circuit is coupled to an input end of the charge pump, and an output end of the charge pump is coupled to the comparator.

A signal received at an input end of the conversion circuit includes an alternating current signal, and a signal output at an output end of the conversion circuit includes a direct current signal.

According to an aspect of an example of the disclosure, a memory is provided, including a memory cell array and a peripheral circuit, and the peripheral circuit includes the foregoing charge pump circuit.

According to an aspect of an example of the disclosure, a memory system is provided, including a controller and the foregoing memory, and the controller is coupled to the memory to control the memory to store data.

According to an aspect of an example of the disclosure, an electronic apparatus is provided, including a host and a memory system coupled to the host, the memory system includes a controller and the foregoing memory, and the controller is coupled to the memory to control the memory to store data.

The technical solutions according to the examples of the disclosure at least include the following beneficial effects:

By designing the conversion circuit to convert the alternating current signal that needs to be processed by the charge pump into a direct current signal, (in a case where the alternating current signal is a high-frequency signal), the charge pump may process the direct current signal converted from the high-frequency signal, instead of directly processing the high-frequency signal, so that an output signal of the charge pump may meet an expected standard.

The above describes optional examples of the present disclosure, and is not intended to limit the disclosure. Any modifications, equivalent substitutions, improvements and the like made within the spirit and principle of the present disclosure shall fall within the scope of the disclosure.

What is claimed is:

1. A charge pump circuit, comprising:
a conversion circuit; and
a charge pump, wherein:
an output end of the conversion circuit is coupled to an input end of the charge pump;
the conversion circuit is configured to convert an alternating current signal received at an input end of the conversion circuit into a direct current signal; and
the charge pump is configured to process the direct current signal to generate an output signal.

2. The charge pump circuit of claim 1, wherein:
the conversion circuit comprises a first conversion circuit and a second conversion circuit;
the first conversion circuit is configured to convert a first alternating current signal received at an input end of the first conversion circuit into a first direct current signal;
the second conversion circuit is configured to convert a second alternating current signal received at an input end of the second conversion circuit into a second direct current signal; and
the charge pump is further configured to process the first direct current signal and the second direct current signal to generate a first output signal and a second output signal.

3. The charge pump circuit of claim 2, wherein:
the first conversion circuit comprises a first low-pass filter, and the second conversion circuit comprises a second low-pass filter;
the first alternating current signal is input at an input end of the first low-pass filter, and the second alternating current signal is input at an input end of the second low-pass filter; and
an output end of the first low-pass filter and an output end of the second low-pass filter are coupled to different input ends of the charge pump, respectively.

4. The charge pump circuit of claim 3, wherein the first low-pass filter comprises M resistors and M capacitors, the second low-pass filter comprises N resistors and N capacitors, both M and N are integers greater than 1, and the M capacitors and the N capacitors are coupled to a ground terminal.

5. The charge pump circuit of claim 2, further comprising a flipping circuit, wherein:
input ends of the flipping circuit are coupled to an output end of the first conversion circuit and an output end of the second conversion circuit, respectively, and output ends of the flipping circuit are coupled to a first input end and a second input end of the charge pump, respectively;
the flipping circuit is configured to: transmit the first direct current signal to the first input end of the charge pump and transmit the second direct current signal to the second input end of the charge pump after first information is received, and transmit the first direct current signal to the second input end of the charge pump and transmit the second direct current signal to the first input end of the charge pump after second information is received; and
the first information is different from the second information.

6. The charge pump circuit of claim 2, wherein:
the charge pump comprises an input circuit, a first P-type metal oxide semiconductor (PMOS) transistor, a second PMOS transistor, and an output circuit, wherein a gate of the first PMOS transistor is coupled to the input circuit, a drain of the first PMOS transistor is coupled to the output circuit, a source of the first PMOS transistor is coupled to a first voltage source, a gate of the second PMOS transistor is coupled to the input circuit, a drain of the second PMOS transistor is coupled to the output circuit, a source of the second PMOS transistor is coupled to the first voltage source, and the output circuit comprises a first capacitor and a second capacitor;
the input circuit is configured to generate a first bias signal to be provided to the first PMOS transistor and a second bias signal to be provided to the second PMOS transistor according to the first direct current signal and the second direct current signal;
the output circuit is configured to charge the first capacitor through a first current to generate the first output signal, and charge the second capacitor through a second current to generate the second output signal; and
the first current includes a drain current of the first PMOS transistor under control of the first bias signal, and the second current includes a drain current of the second PMOS transistor under control of the second bias signal.

7. The charge pump circuit of claim 6, wherein:
the charge pump further comprises a first switch structure and a second switch structure;
one end of the first switch structure is coupled to the drain of the first PMOS transistor, and the other end of the first switch structure is coupled to the output circuit; and
one end of the second switch structure is coupled to the drain of the second PMOS transistor, and the other end of the second switch structure is coupled to the output circuit.

8. The charge pump circuit of claim 6, wherein the input circuit comprises a first input structure and a second input structure, a number of metal oxide semiconductor (MOS) transistors included in the first input structure is the same as a number of MOS transistors included in the second input structure, the gate of the first PMOS transistor is coupled to the first input structure, and the gate of the second PMOS transistor is coupled to the second input structure.

9. The charge pump circuit of claim 8, wherein:
the first input structure comprises: a first current source, a first N-type metal oxide semiconductor (NMOS) transistor, and a second NMOS transistor;
the second input structure comprises: a second current source, a third NMOS transistor, and a fourth NMOS transistor;
the first current source is coupled to a source of the first NMOS transistor and a source of the second NMOS transistor, and the second current source is coupled to a source of the third NMOS transistor and a source of the fourth NMOS transistor;
a gate of the first NMOS transistor and a gate of the third NMOS transistor are coupled to a first input end of the charge pump; and
a gate of the second NMOS transistor and a gate of the fourth NMOS transistor are coupled to a second input end of the charge pump.

10. The charge pump circuit of claim 9, wherein:
the first input structure further comprises a third PMOS transistor and a fourth PMOS transistor;
the second input structure further comprises a fifth PMOS transistor and a sixth PMOS transistor;
a source of the third PMOS transistor, a source of the fourth PMOS transistor, a source of the fifth PMOS transistor, and a source of the sixth PMOS transistor are coupled to the first voltage source;
a drain of the first NMOS transistor, a drain of the third NMOS transistor, a drain of the third PMOS transistor, a gate of the third PMOS transistor, a drain of the fourth PMOS transistor, and a gate of the fifth PMOS transistor are coupled to the gate of the first PMOS transistor; and
a drain of the second NMOS transistor, a drain of the fourth NMOS transistor, a drain of the sixth PMOS transistor, a gate of the sixth PMOS transistor, a drain of the fifth PMOS transistor, and a gate of the fourth PMOS transistor are coupled to the gate of the second PMOS transistor.

11. The charge pump circuit of claim 6, wherein the output circuit comprises a first output structure and a second output structure, a number of MOS transistors included in the first output structure is the same as a number of MOS transistors included in the second output structure, the drain of the first PMOS transistor is coupled to the first output structure, and the drain of the second PMOS transistor is coupled to the second output structure.

12. The charge pump circuit of claim 11, wherein:
the first output structure comprises a fifth NMOS transistor, a sixth NMOS transistor, the first capacitor and a first resistor;
the second output structure comprises a seventh NMOS transistor, an eighth NMOS transistor, the second capacitor and a second resistor;
a drain of the first PMOS transistor is coupled to a drain of the fifth NMOS transistor, a gate of the fifth NMOS transistor, a drain of the sixth NMOS transistor, one end of the first capacitor, and one end of the first resistor;
a source of the fifth NMOS transistor, a source of the sixth NMOS transistor, and the other end of the first capacitor are coupled to a ground terminal;
a drain of the second PMOS transistor is coupled to a drain of the seventh NMOS transistor, a gate of the seventh NMOS transistor, a drain of the eighth NMOS transistor, one end of the second capacitor, and one end of the second resistor;
a source of the seventh NMOS transistor, a source of the eighth NMOS transistor, and the other end of the second capacitor are coupled to the ground terminal; and
the other end of the first resistor and a gate of the eighth NMOS transistor are coupled to a first output end of the charge pump, and the other end of the second resistor and a gate of the sixth NMOS transistor are coupled to a second output end of the charge pump.

13. The charge pump circuit of claim 2, wherein the first alternating current signal comprises a first clock signal, the second alternating current signal comprises a second clock signal, an amplitude of the first direct current signal is positively correlated with a duty cycle of the first clock signal, and an amplitude of the second direct current signal is positively correlated with a duty cycle of the second clock signal.

14. A peripheral circuit, comprising:
a Phase Frequency Detector (PFD);
a charge pump circuit; and
a comparator, wherein:
the charge pump circuit comprises a conversion circuit and a charge pump, an input end of the conversion circuit is coupled to the PFD, an output end of the conversion circuit is coupled to an input end of the charge pump, and an output end of the charge pump is coupled to the comparator; and
a signal received at an input end of the conversion circuit includes an alternating current signal, and a signal output at an output end of the conversion circuit includes a direct current signal.

15. The peripheral circuit of claim 14, further comprising at least one of:
a page buffer, a sense amplifier, a column decoder, a bit line driver, a row decoder, a word line driver, a voltage generator, a control logic unit, a register, an interface, or a data bus.

16. A memory, comprising:
a memory cell array; and
a peripheral circuit, wherein:
the peripheral circuit comprises a charge pump circuit comprising a conversion circuit and a charge pump, wherein an output end of the conversion circuit is coupled to an input end of the charge pump;
the conversion circuit is configured to convert an alternating current signal received at an input end of the conversion circuit into a direct current signal; and
the charge pump is configured to process the direct current signal to generate an output signal.

17. The memory of claim 16, wherein:
the peripheral circuit further comprises: a phase frequency detector (PFD) and a comparator, the PFD is coupled to the input end of the charge pump circuit, and the comparator is coupled to an output end of the charge pump circuit;
the PFD is configured to obtain a first clock signal and a second clock signal to be input to the charge pump circuit according to a plurality of frequency division signals of a write clock (WCK) signal of the memory, wherein a frequency of the first clock signal and the second clock signal are the same as a frequency of the WCK signal, and duty cycles of the first clock signal and the second clock signal are associated with a duty cycle of the WCK signal; and
the comparator is configured to obtain a comparison result signal according to a first output signal and a second output signal of the charge pump, the comparison result signal is configured to indicate a magnitude relationship between a duty cycle of the WCK signal and a target duty cycle.

18. The memory of claim 16, wherein:
the peripheral circuit further comprises at least one of:
a page buffer, a sense amplifier, a column decoder, a bit line driver, a row decoder, a word line driver, a voltage generator, a control logic unit, a register, an interface, or a data bus.

19. The memory of claim 16, wherein:
the conversion circuit comprises a first conversion circuit and a second conversion circuit;
the first conversion circuit is configured to convert a first alternating current signal received at an input end of the first conversion circuit into a first direct current signal;
the second conversion circuit is configured to convert a second alternating current signal received at an input end of the second conversion circuit into a second direct current signal; and
the charge pump is further configured to process the first direct current signal and the second direct current signal to generate a first output signal and a second output signal.

20. The memory of claim 19, wherein:
the first conversion circuit comprises a first low-pass filter, and the second conversion circuit comprises a second low-pass filter;
the first alternating current signal is input at an input end of the first low-pass filter, and the second alternating current signal is input at an input end of the second low-pass filter; and
an output end of the first low-pass filter and an output end of the second low-pass filter are coupled to different input ends of the charge pump, respectively.
